(19) United States
(12) Patent Application Publication
(10) Pub. No.: US 2013/0307628 A1
(43) Pub. Date: Nov. 21, 2013

(54) Radio Frequency Power Amplifier and Packaging and Fabrication Method Thereof

(71) Applicant: NATIONZ TECHNOLOGIES INC., Shenzhen (CN)

(72) Inventors: Pingxi MA, Shenzhen (CN); Liyang ZHANG, Shenzhen (CN); Qian ZHAO, Shenzhen (CN)

(73) Assignee: NATIONZ TECHNOLOGIES INC., Shenzhen (CN)

(21) Appl. No.: 13/947,491

(22) Filed: Jul. 22, 2013

Related U.S. Application Data
(63) Continuation of application No. PCT/CN2011/074957, filed on May 31, 2011.

(30) Foreign Application Priority Data
Jan. 24, 2011 (CN) 201110025537.X

(51) Int. Cl. H03F 3/193; H01L 21/50

(52) U.S. Cl. CPC H03F 3/193; H01L 21/50
USPC 330/296; 330/277; 438/107

(57) ABSTRACT

A radio frequency (RF) power amplifier includes: a pre-stage amplifier configured to amplify an input power to the RF power amplifier; and a post-stage amplifier configured to amplify an output power of the pre-stage amplifier; wherein the pre-stage amplifier comprises a CMOS (Complementary Metal Oxide Semiconductor) amplifier, and the post-stage amplifier comprises a GaAs (Gallium Arsenide) amplifier or a SiGe (Silicon Germanium) amplifier.

### CROSS-REFERENCE TO RELATED APPLICATIONS

The present application is a continuation of PCT/CN2011/074957, filed on May 31, 2011, which claims priority to CN 201110025537.X, filed on Jan. 24, 2011. The disclosures of these applications are hereby incorporated by reference in their entirety.

### BACKGROUND

In the field of producing multi-chip module of a power amplifier, the structure of a conventional power amplifier is shown in FIG. 1. As shown in FIG. 1, a radio frequency power amplifier may include a GaAs (Gallium Arsenide) die for amplifying the signal path; a PHEMT (pseudomorphic high electron mobility transistor) switch die for turning on/off and switching the sending and receiving signal frequency bands; a CMOS (Complementary Metal Oxide Semiconductor) controller die for providing bias and control signals to the signal amplification modules and switch modules. Under different circumstances, the PHEMT Switch die and the CMOS controller die can be skipped. This type of amplifiers has high performance levels, but the cost is on the high side.

Another conventional radio frequency power amplifier is shown in FIG. 2. FIG. 2 is the schematic block diagram of another current power amplifier. The radio frequency power amplifier in FIG. 2 utilizes the CMOS technology to amplify the signal path of the GaAs die in FIG. 1, thereby integrating the CMOS controller and the signal amplifier module. Similarly, in different circumstances, the PHEMT Switch die can be skipped. This type of amplifiers has the advantage of low cost. Technology wise it is difficult to implement. It is also difficult to improve the performance of this type of amplifiers.

In general, a radio frequency power amplifier needs to provide about 27˜35 dBm output power. From the perspectives of power consumption, size and reliability, it is challenging to achieve such level of output power with the CMOS-only amplifiers shown in FIG. 2. The performance level of the CMOS-only amplifiers does not compare well with the GaAs amplifiers shown in FIG. 1. However, even though a number of companies have been able to shrink the size of GaAs dies, the extremely expensive GaAs wafer means that GaAs amplifiers still face cost pressure.

Consequently, it is a major challenge in the field of producing radio frequency amplifiers to simultaneously lower the cost of the radio frequency amplifiers and improve their performance.

### SUMMARY

In one aspect, a radio frequency (RF) power amplifier is provided including: a pre-stage amplifier configured to amplify an input power to the RF power amplifier; and a post-stage amplifier configured to amplify an output power of the pre-stage amplifier; wherein the pre-stage amplifier comprises a CMOS (Complementary Metal Oxide Semiconductor) amplifier, and the post-stage amplifier comprises a GaAs (Gallium Arsenide) amplifier or a SiGe (Silicon Germanium) amplifier.

In some embodiments, the RF power amplifier further includes a switch that is connected to post-stage amplifier, wherein the switch is configured to switch among a plurality of transmission channels of the RF power amplifier and a plurality of reception channels of an external receiver.

In some embodiments, the switch comprises at least one of a Pseudomorphic High Electron Mobility Transistor (PHEMT) switch, a Silicon on Insulator (SOI) switch, or a Silicon on Sapphire (SOS) switch.

In some embodiments, the RF power amplifier further includes a bias or control module, wherein the bias or control module is configured to provide bias or control signal to the pre-stage amplifier and the post-stage amplifier.

In some embodiments, the RF power amplifier further includes a bias or control module, wherein the bias or control module is configured to provide bias or control signal to the pre-stage amplifier, the post-stage amplifier, and the switch.

In some embodiments, the RF power amplifier further includes a CMOS bias circuit connected with the pre-stage power amplifier.

In some embodiments, the RF power amplifier is a three-level amplifier, wherein the first and second level amplification is provided by the pre-stage power amplifier, and the third level amplification is provided by the post-stage power amplifier.

In some embodiments, the RF power amplifier is a three-level amplifier, wherein the first level amplification is provided by the CMOS pre-stage power amplifier, and second and third level amplification is provided by the post-stage power amplifier.

In some embodiments, the RF power amplifier is a three-level amplifier, wherein the first level amplification is provided by the CMOS pre-stage power amplifier; the second level amplification is provided by a SiGe post-stage power amplifier; and the third level amplification is provided by a GaAs post-stage power amplifier.

In some embodiments, the RF power amplifier is a three-level amplifier, wherein the first level amplification is provided by the CMOS pre-stage power amplifier; the second level amplification is provided by a GaAs post-stage power amplifier; and the third level amplification is provided by a SiGe post-stage power amplifier.

In some embodiments, the RF power amplifier is a (m+n)-level amplifier, wherein the CMOS pre-stage power amplifier provides m levels of amplification, and the post-stage power amplifier provides n levels of amplification, wherein m and n are natural numbers, and m+n is greater than 3.

In another aspect, a method of packaging a RF power amplifier is provided, wherein the RF power amplifier includes a substrate, a CMOS die, a GaAs die or a SiGe die or both, and a Pseudomorphic High Electron Mobility Transistor (PHEMT) die or Silicon on Insulator (SOI) die or Silicon on Sapphire (SOS) die, the method including: disposing the CMOS die, the GaAs die or the SiGe die or both, and the PHEMT die or the SOI die or the SOS die over the substrate.

In some embodiments, the method further includes: electrically connecting the CMOS die to the substrate; electrically connecting the CMOS die to the GaAs die or the SiGe die or both; and electrically connecting the GaAs die or the SiGe die or both to the PHEMT die or the SOI die or the SOS die.

In some embodiments, the method further includes: electrically connecting the CMOS die to the substrate; setting the GaAs die or the SiGe die or both, the PHEMT die or the SOI die or the SOS die on the upper side of the CMOS die; electrically connecting the GaAs die or the SiGe die or both to the CMOS die; and electrically connecting the PHEMT die or the SOI die or the SOS die to the substrate.

In some embodiments, the method further includes: disposing the CMOS die over the substrate; disposing the GaAs die or the SiGe die or both, the PHEMT die or the SOI die or the SOS die on the upper side of the CMOS die; electrically connecting the GaAs die or the SiGe die or both, the PHEMT die or the SOI die or the SOS die to the CMOS die; and electrically connecting the CMOS die to the substrate.

In some embodiments, the GaAs die or the SiGe die or both, the PHEMT die or the SOI die or the SOS die are electrically connected to the CMOS die via copper pillars.

In some embodiments, the method further includes: disposing the GaAs die or the SiGe die or both, the PHEMT die or the SOI die or the SOS die to the substrate; disposing the CMOS die to the upper side of the GaAs die or the SiGe die or both, the PHEMT die or the SOI die or the SOS die; electrically connecting the CMOS die to the GaAs die or the SiGe die or both, the PHEMT die or the SOI die or the SOS die; and electrically connecting the CMOS die to the substrate.

In some embodiments, the CMOS die is connected via copper pillars to GaAs die or the SiGe die or both, the PHEMT die or the SOI die or the SOS die.

In some embodiments, the step of electrically connecting is achieved via wire bonding.

In another aspect, a method of producing a RF power amplifier is provided including: forming a pre-stage power amplifier with CMOS technology; forming a post-stage power amplifier with GaAs technology or SiGe technology or both; and producing a switch for the RF power amplifier with the PHEMT technology, the SOS technology or the SOI technology.

### BRIEF DESCRIPTION OF THE DRAWINGS

FIG. 1 is schematic diagram of the structure of a prior art radio frequency power amplifier;

FIG. 2 is a schematic diagram of the structure of another prior art radio frequency power amplifier;

FIG. 3 is a schematic diagram of the structure of a radio frequency power amplifier according to some embodiments.

FIG. 4 is a diagram of a packaging method of a radio frequency power amplifier according to some embodiments;

FIG. 5 is a diagram of another packaging method of a radio frequency power amplifier according to some embodiments;

FIG. 6 is a diagram of yet another packaging method of a radio frequency power amplifier according to some embodiments;

FIG. 7 is a diagram of yet another packaging method of radio frequency power amplifier according to some embodiments.

### DETAILED DESCRIPTION

Various embodiments are described in detail below with reference to the drawings. Like reference numbers may be used to denote like parts throughout the figures.

Abbreviations used in present disclosure may include: PHEMT (Pseudomorphic HEMT): pseudomorphic high electron mobility transistor); CMOS: complementary metal oxide semiconductor; GaAs: gallium arsenide; SOI: Silicon on insulator; SOS: sapphire on silicon; SiGe: silicon germanium. The reference numbers in FIG. 4 to FIG. 7 may indicate: 400, substrate, 401, CMOS die, 402, GaAs/SiGe die, 403, PHEMT/SOI/SOS die, 500, binding wire, 600, copper pillar.

The present disclosure discloses a radio frequency power amplifier using a CMOS die as the pre-stage circuit, a GaAs and/or a SiGe die as the post-stage circuit. As such, the size of GaAs die or the SiGe die within the integrated module of radio frequency power amplifier can be significantly reduced, as with the cost of producing them. In the meantime, the performance of the radio frequency power amplifier reaches a performance level comparable to power amplifiers using GaAs die or SiGe die alone.

Below is a description of the principles and characteristics of various embodiments with reference to the drawings. The examples used are for illustration purpose only, and are not to limit the scope of the claimed embodiments.

The symbol “/” in the present disclosure indicates “or.” For example, PHEMT/SOI/SOS indicates PHEMT or SOI or SOS.

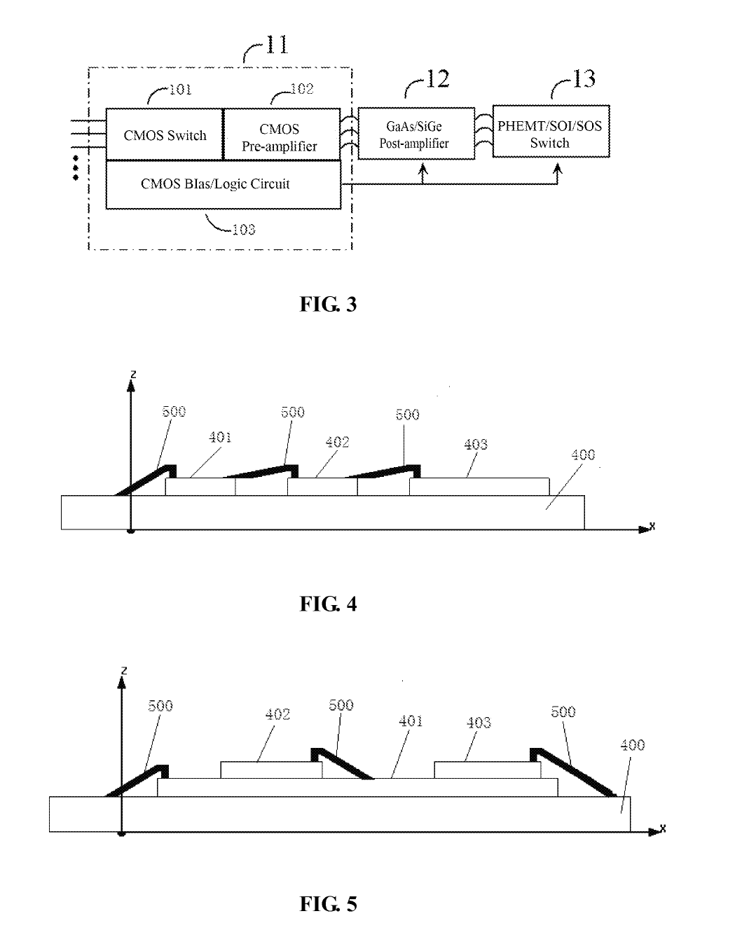

A schematic diagram of the structure of the radio frequency power amplifier according to some embodiments is shown in FIG. 3. As shown, the radio frequency power amplifier includes the sequentially-connected CMOS die 11, GaAs or SiGe die 12, and PHEMT/SOI (Silicon-On-Insulator)/SOS (Silicon-on-Sapphire) die 13.

CMOS die 11 provides a pre-stage circuit for the radio frequency power amplifier. The core circuit in CMOS die 11 is CMOS pre-stage amplifier (or pre-amplifier) 102. CMOS pre-amplifier 102 is configured to perform input matching as well as achieving appropriate power gain to result in appropriate output power (typically less than 23 dBm). That is, CMOS pre-amplifier 102 is configured to preliminarily amplify the input power. CMOS pre-amplifier utilizes CMOS process to realize a gain around 20 dB gain, resulting in the pre-amplifier having an output power of less than 23 dBm. Here, the output power is defined as half of the mold of the product of the conjugate of the electrical current signal at the output end of the pre-stage power amplifier and the voltage signal at the output end. Meanwhile, 50 ohm matching for the input ports of module is achieved.

The CMOS pre-amplifier can comprise two stages of amplification circuits. The first stage circuit is configured to match and increase the gain. The second stage circuit is configured for further increase of the output power and gain. CMOS Switch 101 can be integrated into CMOS die 11. CMOS switch 101 can be configured for input signal switching in multi-mode multi-band applications. For example, GSM (Global System for Mobile Communications), EDGE (Enhanced Data Rate for GSM Evolution) and TDSCDMA (Time Division-Synchronous Code Division Multiple Access) can all use CMOS switch as signal switch, and adopting the CMOS process to realize the switching of the signals at the input ports. Because the maximum input signal is less than 5 dBm, using CMOS process to realize on/off and switching would not encounter the bottleneck of linearity. Adopting CMOS process to realize switching is therefore technically viable.

CMOS bias circuit 103 can also be integrated into CMOS die 11. CMOS bias circuit 103 can be configured for biasing the pre-stage and post-stage power amplifier, as well as providing a control interface for the whole module of the radio frequency power amplifier, such as control signals of the channel switch. Using CMOS technology to realize the bias and logic control of the whole module of radio frequency power amplifier, CMOS bias circuit can further comprise band gap circuit, LDO (low dropout linear regulator) circuit, logic control circuit.

In some other embodiments, the CMOS switch and CMOS bias circuit within the CMOS die can sometimes be removed, such as when used in radio frequency power amplifier on the transmitting front of mobile phone in single mode application. In other embodiments of the inventions disclosed in the present application, the CMOS die can further comprise passive devices such as inductors, capacitors, transformers, switches, diplexers, filters.

GaAs or SiGe die 12 provides post-stage circuits (i.e., post stage power amplifier, same below) of the radio frequency power amplifier, which is used to improve the performance of the post-stage (especially the last stage) of the radio frequency power amplifier. If using the GaAs die, the GaAs die provides GaAs post-stage power amplifier; if using SiGe die, the SiGe die provides post-stage power amplifier. They are all able to improve the performance of the radio frequency power amplifier. In some other embodiments, GaAs die and SiGe die can be used together to provide post-stage circuit for a radio frequency power amplifier.

Among the radio frequency power amplifiers using CMOS die and GaAs die and/or SiGe die, the following combinations may be possible:
(1) CMOS die contributes to the first stage gain, GaAs or SiGe die contributes to the second stage gain, i.e., CMOS die provides a first-stage amplifier, GaAs or SiGe die provides a second stage amplifier;
(2) CMOS die contributes to the first stage and second stage gain, GaAs or SiGe die contributes to the third stage gain, i.e., CMOS die provides a first stage amplifier and a second stage amplifier, GaAs die or SiGe die provides a third stage amplifier;
(3) CMOS die contributes to the first stage gain, GaAs die or SiGe die contributes to the second stage and third stage gain, i.e., CMOS die provides first-stage amplifier, GaAs die or SiGe die provides a second stage and a third stage amplifier;
(4) CMOS die contributes to the first stage gain, SiGe die contributes a second stage gain, GaAs die contributes a third stage gain, i.e., CMOS die provides a first-stage amplifier, SiGe die provides a second stage amplifier, GaAs die provides a third-stage amplifier; Or, CMOS die contributes a first stage gain, GaAs die contributes a second stage gain, SiGe die contributes a third stage gain, i.e., CMOS die provides a first-stage amplifier, GaAs die provides a second stage amplifier, SiGe die provides a third-stage amplifier;
(5) In the designs for gains greater than three stages, CMOS die can be at pre-m stage, GaAs die and/or SiGe can at post-n stage, with m+n being the total number of stages of radio frequency power amplifier, i.e., CMOS die provides pre-m stage amplifier, GaAs die and/or SiGe die provides post-n stage amplifier.

CMOS pre-stage amplifier 102 can realize a gain of about 20 dB. Compared with the gain of around 30 dB in conventional radio frequency power amplifiers, there is a gap of about 10 dB. GaAs process and/or SiGe process are used to realize the post-stage of the amplifier, designing a gain of about 10 dB, an output power of 30˜35 dBm, and an output impedance match of 50 ohm, the input impedance matches the output port of the CMOS pre-amplifier.

The PHEMT/SOI/SOS die 13 that is attached behind the GaAs die and/or SiGe die provides PHEMT Switch, SOI Switch or SOS Switch as signal channel switch and/or as device to adjust load impedance. That is, one can use PHEMT switch, SOI switch or SOS switch as switch for radio frequency power amplifier. This switch is configured to switch multiple transmitting channels of radio frequency power amplifier and multiple receiving channels of external receivers.

The following are descriptions of packaging methods for the disclosed radio frequency power amplifier, which comprises a CMOS die, a GaAs or SiGe die, a PHEMT/SOI/SOS die and a substrate.

A diagram showing one of the disclosed packaging methods for the radio frequency power amplifier is illustrated in FIG. 4. FIG. 4 illustrates the WireBond (binding wire) packaging method. As shown, CMOS die 401, GaAs/SiGe die 402, and PHEMT/SOI/SOS die 403 may be arranged in parallel over substrate 400. They can be connected via WireBond 500. Moreover, each die can form ground connection through a back hole. In FIG. 4, CMOS die 401 is electrically connected to the substrate; CMOS die 401 and GaAs die and/or SiGe die 402 are electrically connected, GaAs die and/or SiGe and PHEMT die 402/SOI die/SOS die 403 are electrically connected. Electrical connections can be achieved via WireBond.

A schematic diagram of another disclosed packaging method of the radio frequency power amplifier is illustrated in FIG. 5. FIG. 5 illustrates the packaging method of combining stacked die and WireBond. As shown, CMOS die 401 is placed face up over substrate 400. GaAs/SiGe die 402 and PHEMT/SOI/SOS CMOS die 403 are placed face up on the top of CMOS die 401. They are also connected via WireBond 500. In FIG. 5, CMOS die 401 is placed on (and electrically connected to) substrate 400; GaAs die and/or SiGe die 402 and PHEMT die/SOI die/SOS die 403 are placed on the top of CMOS die 401. The GaAs die and/or SiGe die 402 and CMOS die 401 are electrically connected. Moreover, PHEMT die/SOI die/SOS die 403 is electrically connected to the substrate. Electrical connections can be achieved via WireBond.

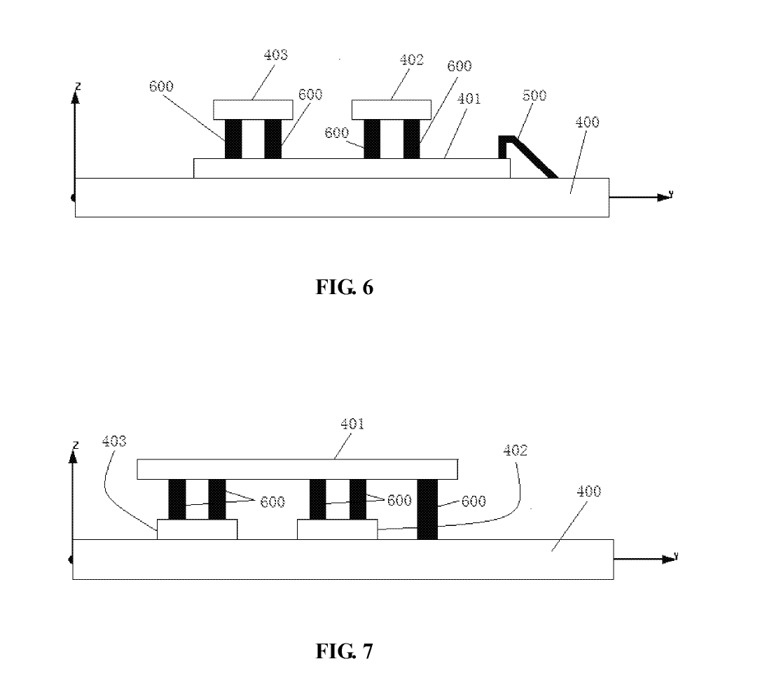

A schematic diagram of yet another disclosed packaging method of the radio frequency power is illustrated in FIG. 6. FIG. 6 illustrates a method of packaging that combines FlipChip (upside down) and WireBond. As shown, CMOS die 401 is placed face up on substrate 400, GaAs/SiGe die 402 and PHEMT/SOI/SOS die 403 are placed face down on the top of CMOS die 401. GaAs die/SiGe die 402 and PHEMT/SOI/SOS die 403 are electrically connected with CMOS die 401 via Pillar Bump 600. CMOS die 401 is electrically connected to substrate 400 via WireBond 500. In this kind of packaging method, CMOS die is placed on the substrate, and dies of smaller size such as GaAs/SiGe/PHEMT die are placed upside down and are connected to the reserved interface of CMOS die via methods such as Pillar Bump. GaAs/SiGe/PHEMT die can be regarded as patches for the CMOS die. In FIG. 6, CMOS die 401 is placed on substrate 400. GaAs die and/or SiGe die 402 and PHEMT die/SOI die/SOS die 403 are placed on the top of CMOS die 401. GaAs die and/or SiGe die 402, and PHEMT die/SOI die/SOS die 403 are electrically connected to CMOS die 401. CMOS die 401 is electrically connected to the substrate. Electrical connections can be achieved via WireBond.

A schematic diagram of yet another disclosed packaging method of the radio frequency power amplifier is illustrated in FIG. 7. FIG. 7 illustrates a twofold FlipChip upside down packaging method. As shown, GaAs die/SiGe die 402, and PHEMT/SOI/SOS die 403 are placed upside down on CMOS die 401, and are electrically connected to CMOS die 401 via Pillar Bump 600. CMOS die 401 is placed upside down on substrate 400. CMOS die 401 and substrates 400 are electrically connected via Pillar Bump 600. In FIG. 7, GaAs die and/or SiGe die 402 and PHEMT die/SOI die/SOS die 403 are placed on the substrate. CMOS die 401 is placed on the top of GaAs die and/or SiGe die 402 and PHEMT die/SOI Die/SOS die 403. CMOS die 401, GaAs die and/or SiGe die 402, and PHEMT die/SOI Die/SOS die 403 are electrically connected (via the copper pillars). CMOS die 401 and substrates 400 are also connected via the copper pillars. Electrical connections can be achieved by WireBond.

The radio frequency power amplifier in some of the disclosed embodiments can be configured as a multi-chip module group for the front-end transmitter of mobile phones with four modes: GSM Dual Band/TDSCDMA Dual Band.

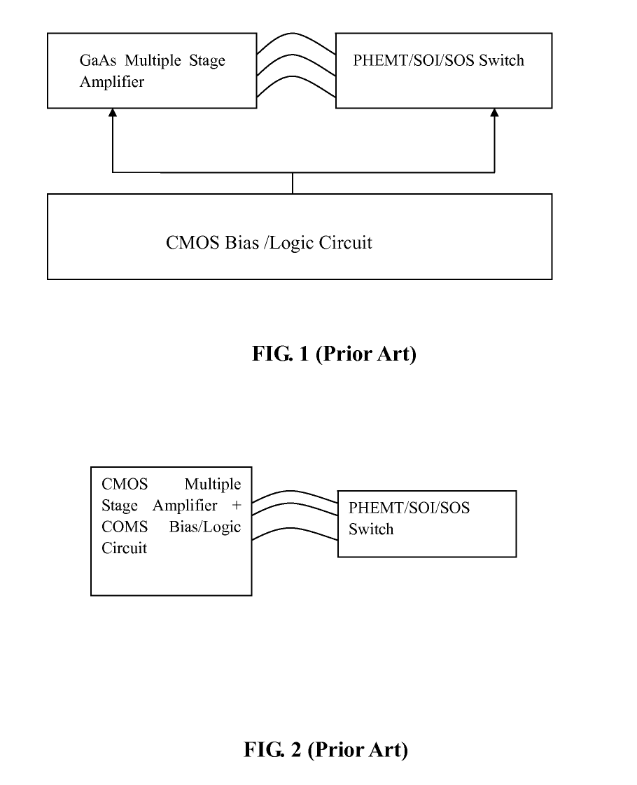

The disclosed embodiments herein utilizes CMOS die to replace the pre-stage(s) of the multi-stage GaAs amplifier in conventional solutions shown in FIG. 1. From a technical perspective, it is feasible to design pre-stage amplifier circuits using CMOS process to achieve an output power of 23 dBm or less, a gain around 20 dB and input impedance matching Coupled with post-stage high performance die produced with GaAs process, SiGe process or SiGe+GaAs process, the performance of the module disclosed herein can reach the performance level of the conventional solutions (which utilizes a pure GaAs or SiGe process). Compared with the pure GaAs or SiGe conventional solutions, the size of the GaAs or SiGe die in the module can be significantly reduced. As a result, the cost of producing the whole module of the disclosed radio frequency power amplifier can be significantly reduced.

The disclosed embodiments herein utilizes GaAs/SiGe amplifier as patch to replace the post-stage(s) of the CMOS amplifier in conventional solutions shown in FIG. 2. From a technical perspective, GaAs/SiGe amplifier patch requires only a small area of power tube array, and possibly a small amount of bias circuits and compensation circuits. Higher performance on key indicators such as reliability and linearity can be achieved via small-sized patches at the cost of slight increase of packaging cost and difficulty. In the mean time, power consumption is lower than that in conventional solutions shown in FIG. 2.

At least some of the disclosed embodiments overcome at least some of the following difficulties in design and implementation:

(1) When using the packaging methods of WireBond in FIG. 4, FIG. 5 or FIG. 6, the parasitic inductance effect caused by limited grounding bond wire makes the chip not well-connected to the ground. When using the upside down packaging method illustrated in FIG. 7, the chip can be connected to the ground well. However, the method in FIG. 7 requires advanced processing technology to grow the pillar bumps.

(2) When using the multi-die integrated module design, it may be difficult to estimate and test spatial electromagnetic coupling, which may require electromagnetic simulation modeling design.

Although there is certain degree of difficulty in design and implementation, at least some of the disclosed embodiments overcome the difficulties in design and enables the radio frequency power amplifier to be realized using existing technological level.

As such, at least some of the disclosed embodiments reduce the cost of production without sacrificing performance.

A method for producing radio frequency power amplifiers is also provided, e.g., using a CMOS process to produce the pre-stage CMOS die, using a GaAs process and/or SiGe process to produce the post-stage GaAs die and/or SiGe die of the radio frequency power amplifier, attaching the GaAs die and/or SiGe to the CMOS die. The GaAs die and/or SiGe die can then be placed on the same substrate with the CMOS die, thereby producing the radio frequency power amplifier. Further, PHEMT process may be used to produce PHEMT die, or SOI process may be used to produce SOI die, or SOS process may be used to produce SOS die. PHEMT die, SOI die or SOS die can be attached to the GaAs/or SiGe die. PHEMT die, SOI die or SOS die can then be placed on the same substrate with the CMOS die, the GaAs die and/or SiGe die.

The disclosed methods make it possible to manufacture radio frequency power amplifiers of relatively high performance with reduced cost of production.

All references cited in the description are hereby incorporated by reference in their entirety. While the disclosure has been described with respect to a limited number of embodiments, those skilled in the art, having benefit of this disclosure, will appreciate that other embodiments can be advised and achieved which do not depart from the scope of the description as disclosed herein.

1. A radio frequency (RF) power amplifier, comprising:
a pre-stage amplifier configured to amplify an input power to the RF power amplifier; and
a post-stage amplifier configured to amplify an output power of the pre-stage amplifier;
wherein the pre-stage amplifier comprises a CMOS (Complementary Metal Oxide Semiconductor) amplifier, and
the post-stage amplifier comprises a GaAs (Gallium Arsenide) amplifier or a SiGe (Silicon Germanium) amplifier.

2. The RF power amplifier of claim 1, further comprising a switch that is connected to post-stage amplifier, wherein the switch is configured to switch among a plurality of transmission channels of the RF power amplifier and a plurality of reception channels of an external receiver.

3. The RF power amplifier of claim 2, wherein the switch comprises at least one of a Pseudomorphic High Electron Mobility Transistor (PHEMT) switch, a Silicon on Insulator (SOI) switch, or a Silicon on Sapphire (SOS) switch.

4. The RF power amplifier of claim 1, further comprising a bias or control module, wherein the bias or control module is configured to provide bias or control signal to the pre-stage amplifier and the post-stage amplifier.

5. The RF power amplifier of claim 2, further comprising a bias or control module, wherein the bias or control module is configured to provide bias or control signal to the pre-stage amplifier, the post-stage amplifier, and the switch.

6. The RF power amplifier of claim 1, further comprising a CMOS bias circuit connected with the pre-stage power amplifier.

7. The RF power amplifier of claim 1, wherein the RF power amplifier is a three-level amplifier, wherein the first and second level amplification is provided by the pre-stage power amplifier, and the third level amplification is provided by the post-stage power amplifier.

8. The RF power amplifier of claim 1, wherein the RF power amplifier is a three-level amplifier, wherein the first level amplification is provided by the CMOS pre-stage power amplifier, and second and third level amplification is provided by the post-stage power amplifier.

9. The RF power amplifier of claim 1, wherein the RF power amplifier is a three-level amplifier, wherein the first level amplification is provided by the CMOS pre-stage power amplifier; the second level amplification is provided by a SiGe post-stage power amplifier; and the third level amplification is provided by a GaAs post-stage power amplifier.

10. The RF power amplifier of claim 1, wherein the RF power amplifier is a three-level amplifier, wherein the first level amplification is provided by the CMOS pre-stage power amplifier; the second level amplification is provided by a GaAs post-stage power amplifier; and the third level amplification is provided by a SiGe post-stage power amplifier.

11. The RF power amplifier of claim 1, wherein the RF power amplifier is a (m+n)-level amplifier, wherein the CMOS pre-stage power amplifier provides m levels of amplification, and the post-stage power amplifier provides n levels of amplification, wherein m and n are natural numbers, and m+n is greater than 3.

12. A method of packaging a RF power amplifier, wherein the RF power amplifier comprises a substrate, a CMOS die, a GaAs die or a SiGe die or both, and a Pseudomorphic High Electron Mobility Transistor (PHEMT) die or Silicon on Insulator (SOI) die or Silicon on Sapphire (SOS) die, the method comprising: disposing the CMOS die, the GaAs die or the SiGe die or both, and the PHEMT die or the SOI die or the SOS die over the substrate.

13. The method of claim 12, further comprising:
electrically connecting the CMOS die to the substrate;
electrically connecting the CMOS die to the GaAs die or the SiGe die or both; and
electrically connecting the GaAs die or the SiGe die or both to the PHEMT die or the SOI die or the SOS die.

14. The method of claim 12, further comprising:
electrically connecting the CMOS die to the substrate;
setting the GaAs die or the SiGe die or both, the PHEMT die or the SOI die or the SOS die on the upper side of the CMOS die;
electrically connecting the GaAs die or the SiGe die or both to the CMOS die; and
electrically connecting the PHEMT die or the SOI die or the SOS die to the substrate.

15. The method of claim 12, further comprising:
disposing the CMOS die over the substrate;
disposing the GaAs die or the SiGe die or both, the PHEMT die or the SOI die or the SOS die on the upper side of the CMOS die;
electrically connecting the GaAs die or the SiGe die or both, the PHEMT die or the SOI die or the SOS die to the CMOS die; and
electrically connecting the CMOS die to the substrate.

16. The method of claim 15, wherein the GaAs die or the SiGe die or both, the PHEMT die or the SOI die or the SOS die are electrically connected to the CMOS die via copper pillars.

17. The method of claim 12, further comprising:
disposing the GaAs die or the SiGe die or both, the PHEMT die or the SOI die or the SOS die to the substrate;
disposing the CMOS die to the upper side of the GaAs die or the SiGe die or both, the PHEMT die or the SOI die or the SOS die;
electrically connecting the CMOS die to the GaAs die or the SiGe die or both, the PHEMT die or the SOI die or the SOS die; and
electrically connecting the CMOS die to the substrate.

18. The method of claim 17, wherein the CMOS die is connected via copper pillars to GaAs die or the SiGe die or both, the PHEMT die or the SOI die or the SOS die.

19. The method of claim 12, wherein the step of electrically connecting is achieved via wire bonding.

20. A method of producing a RF power amplifier, comprising:
forming a pre-stage power amplifier with CMOS technology;
forming a post-stage power amplifier with GaAs technology or SiGe technology or both; and
producing a switch for the RF power amplifier with the PHEMT technology, the SOS technology or the SOI technology.
